(19) United States
(12) Patent Application Publication
(10) Pub. No.: US 2006/0006416 A1
(43) Pub. Date: Jan. 12, 2006

(54) Bipolar transistor with nonselective epitaxial base and raised extrinsic base

(76) Inventors: Nathan R. Perkins, Fort Collins, CO (US); Thomas E. Dungan, Fort Collins, CO (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/886,461

(22) Filed: Jul. 7, 2004

(51) Int. Cl. H01L 29/739

(52) U.S. Cl. 257/197

(57) ABSTRACT

A method for forming a transistor that includes forming an intrinsic base on a substrate using nonselective epitaxy and forming a raised extrinsic base on the intrinsic base. The nonselective epitaxy used to form the intrinsic base avoids the costly, complex, and defect prone process of selective epitaxy while the raised extrinsic base avoids the high resistance, high noise, low gain, and base contact problems found in prior transistors having thin base regions.

### BACKGROUND

A bipolar transistor is a semiconductor device with wide applicability for analog and digital applications. Small signals applied to a base of a bipolar transistor may be used to modulate large changes to current through its emitter and collector.

A bipolar transistor may be fabricated using diffusion and/or epitaxial deposition to form the emitter, base, and collector layers. Examples of semiconductor materials that may be used to form a bipolar transistor are numerous and include silicon, silicon germanium alloys, and a wide range of III-V and II-VI semiconductors.

The base of a bipolar transistor may be formed by depositing semiconductor materials onto a substrate using epitaxy. Epitaxy or epitaxial growth may be defined as a process of depositing a thin layer of single crystal material over a single crystal substrate, e.g. through chemical vapor deposition (CVD). Selective epitaxy may be defined as a process for epitaxial growth of a semiconductor material onto a selected area of a substrate. Nonselective epitaxy may be defined as a process for epitaxial growth of a semiconductor material onto an entire substrate area.

The base of a bipolar transistor may be formed using selective epitaxy. An example process for forming a base using selective epitaxy may include depositing a dielectric material onto a substrate, forming a window in the dielectric material to expose a selected surface area of the substrate, and then using epitaxy to deposit a semiconductor material for the base onto the surface of the substrate through the window. Unfortunately, a bipolar transistor having a base formed using selective epitaxy may be expensive and prone to defects caused by the relatively complex process steps of selective epitaxy.

The base of a bipolar transistor may be formed using nonselective epitaxy. An example process for forming a base using nonselective epitaxy may include depositing a semiconductor material for the base onto a substrate using epitaxy and then forming a base contact onto the deposited semiconductor material. Unfortunately, forming a base contact onto an epitaxially deposited material may be difficult in high speed transistors having thin base regions. In addition, the thin base regions in high speed transistors may exhibit higher resistance, lower gain, and greater noise.

### SUMMARY OF THE INVENTION

A method for forming a transistor is disclosed that includes forming an intrinsic base on a substrate using nonselective epitaxy and forming a raised extrinsic base on the intrinsic base. The nonselective epitaxy used to form the intrinsic base avoids the costly, complex, and defect prone process of selective epitaxy while the raised extrinsic base avoids the high resistance, high noise, low gain, and base contact problems found in prior transistors having thin base regions.

Other features and advantages of the present invention will be apparent from the detailed description that follows.

### BRIEF DESCRIPTION OF THE DRAWINGS

The present invention is described with respect to particular exemplary embodiments thereof and reference is accordingly made to the drawings in which:

FIGS. 1a-1e show a series of process steps for forming a transistor according to the present techniques;

FIG. 2 shows a transistor including a raised extrinsic base according to the present techniques.

### DETAILED DESCRIPTION

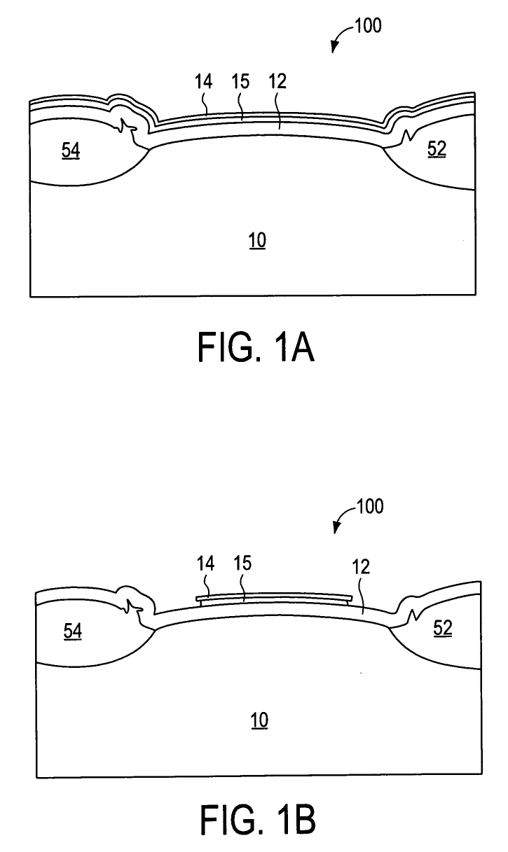

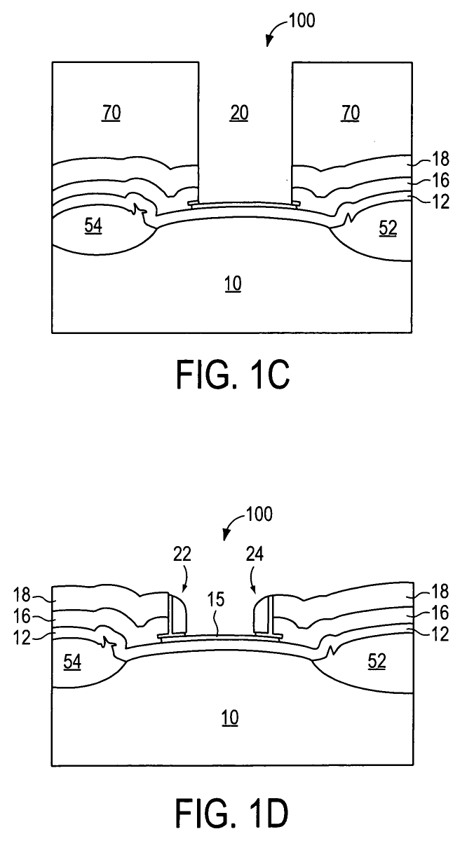

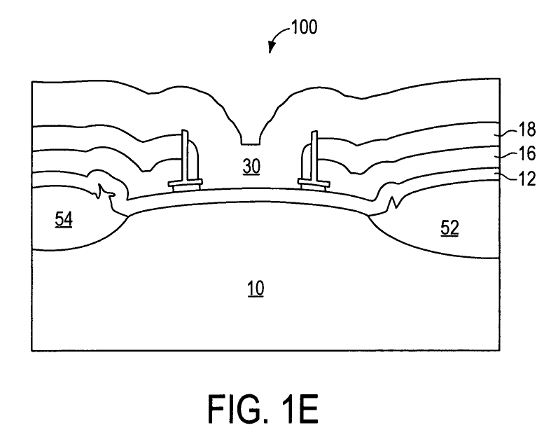

FIGS. 1a-1e show a series of process steps for forming a transistor 100 according to the present techniques. The transistor 100 is formed on a substrate 10. In one embodiment, the substrate 10 is a silicon substrate. The substrate 10 may alternatively be a silicon-on-insulator substrate. A set of dielectric regions 52-54 are formed on the substrate to provide isolation for the transistor 100.

A semiconductor material 12 is deposited (FIG. 1a) epitaxially and non-selectively over the entire substrate 10, e.g. over an entire wafer containing the substrate 10. In one embodiment, the semiconductor material 12 is single crystal silicon-germanium. The semiconductor material 12 provides an intrinsic base for the transistor 100.

In one embodiment, boron is deposited with the epitaxial growth of the semiconductor material 12. For example, the wafer containing the substrate 10 may be contained in a reaction chamber that includes diborane which reacts to deposit boron into the semiconductor material 12.

A pair of etch stop layers 14-15 are deposited (FIG. 1a) onto the semiconductor material 12. The etch stop layers 14-15 provide an etch stop for subsequent process steps. The etch stop layers 14-15 may include silicon nitride and/or silicon oxide dielectrics.

The etch stop layers 14-15 are then patterned (FIG. 1b) to remain only over an active portion of the transistor 100.

A polysilicon material 16 (FIG. 1c) for the raised extrinsic base of the transistor 100 is deposited nonselectively onto the semiconductor material 12 and the patterned etch stop layer 14. The polysilicon material 16 in one embodiment is deposited using chemical vapor deposition. The polysilicon material 16 is then heavily doped (p-type) using an implantation step. The polysilicon material 16 may not be implanted if it is deposited using in-situ p-type doping.

A dielectric material 18 (FIG. 1c) is deposited onto the polysilicon material 16. The dielectric material 18 provides isolation between the emitter and base junctions of the transistor 100. The dielectric material 18 in one embodiment is silicon-dioxide.

A photolithography step is then used to pattern an opening 20 (FIG. 1c) into the polysilicon material 16 and the dielectric material 18. The opening 20 is formed by etching through the dielectric material 18 and the polysilicon material 16 and stopping at the etch stop layer 15. The photo-resist 70 from the photolithography step is then removed.

A set of spacers 22-24 (FIG. 1d) are then formed into the opening 20. For example, the spacers 22-24 may include silicon nitride and/or silicon oxide dielectrics.

A polysilicon material 30 (FIG. 1e) is deposited to form the emitter of the transistor 100. The polysilicon material 30 may be in situ doped or implanted.

A series of thermal cycles are then applied to diffuse the dopant from the polysilicon material 30 into the semiconductor material 12 and form the emitter-base junction of the transistor 100.

The spacers 22-24 isolate the polysilicon material 30 (the emitter) from the polysilicon material 16 (the raised extrinsic base).

A photolithography step is then used to define a base contact region. The polysilicon and the semiconductor material that is not connected to the device is then etched away. Metal silicide regions are then formed followed by interconnects.

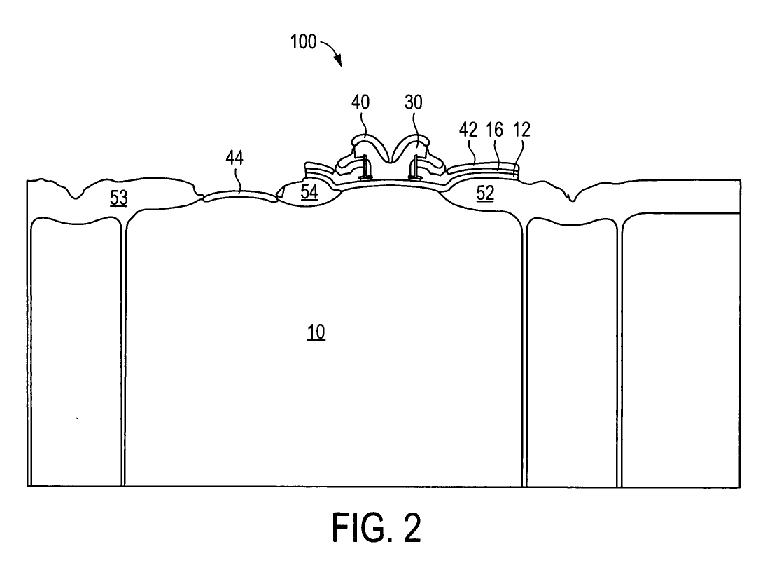

FIG. 2 shows the resulting transistor 100 including the raised extrinsic base 16. Also shown is an emitter contact 40, a base contact 42 and a collector contact 44 each of self-aligned silicide. In addition, the dielectric material 54 that isolates the emitter contact 40 from the collector contact 44 and the dielectric region 52-53 including deep trenches that isolate the transistor 100 from other devices contained on the substrate 10 are shown.

The raised extrinsic base 16 provides a location for performing base implants and for forming base contacts using silicides that avoids the active area of the transistor 100. In addition, the raised extrinsic base 16 may be used to directly contact the active regions of the transistor 100 without the cost and complexity of selective epitaxy. Moreover, the opening 20 in the raised extrinsic base 16 enables the use of the self-aligned spacers 22-24 which may be more robust and repeatable for producing minimum emitter dimensions without complex photolithography.

The present teaching may be applied to form transistors with multiple emitters—often referred to as fingers or stripes. Multi-emitter devices according to the present teachings may be employed in higher power applications, e.g. amplifiers.

The foregoing detailed description of the present invention is provided for the purposes of illustration and is not intended to be exhaustive or to limit the invention to the precise embodiment disclosed. Accordingly, the scope of the present invention is defined by the appended claims.

What is claimed is:

1. A method for forming a transistor, comprising:
forming an intrinsic base on a substrate using nonselective epitaxy;
forming a raised extrinsic base on the intrinsic base.

2. The method of claim 1, wherein forming an intrinsic base comprises forming a silicon-germanium layer on the substrate.

3. The method of claim 1, wherein forming a raised extrinsic base comprises depositing a polysilicon material using nonselective epitaxy.

4. The method of claim 3, further comprising:
forming an etch stop on the intrinsic base;
patterning the etch stop.

5. The method of claim 4, wherein forming the raised extrinsic base using nonselective epitaxy comprises forming the raised extrinsic base on the etch stop and the intrinsic base.

6. The method of claim 5, further comprising forming a dielectric on the raised extrinsic base.

7. The method of claim 6, further comprising:
etching an opening in the dielectric and the raised extrinsic base down to the etch stop;
forming an emitter in the opening.

8. The method of claim 7, wherein forming an emitter comprises:
forming a set of spacers in the opening;
depositing a polysilicon material into the opening.

9. The method of claim 1, further comprising forming a base contact onto the raised extrinsic base.

10. A transistor, comprising:
intrinsic base formed on a substrate using nonselective epitaxy;
raised extrinsic base on the intrinsic base.

11. The transistor of claim 10, wherein the intrinsic base comprises a silicon-germanium layer.

12. The transistor of claim 10, wherein the raised extrinsic base comprises a polysilicon material.

13. The transistor of claim 12, wherein the polysilicon material is deposited using nonselective epitaxy.

14. The transistor of claim 10, wherein the raised extrinsic base is formed on an etch stop on the intrinsic base.

15. The transistor of claim 14, further comprising a dielectric on the raised extrinsic base.

16. The transistor of claim 15, further comprising an emitter formed in an opening in the dielectric and the raised extrinsic base.

17. The transistor of claim 16, wherein the emitter comprises a polysilicon material deposited into the opening.

18. The transistor of claim 10, further comprising a base contact on the raised extrinsic base.
